(19) United States
(12) Patent Application Publication
(10) Pub. No.: US 2012/0133353 A1
(43) Pub. Date: May 31, 2012

(54) POWER-SUPPLY-VOLTAGE DETECTING CIRCUIT

(75) Inventor: Hisami Saitou, Fukuoka-ken (JP)

(73) Assignee: Kabushiki Kaisha Toshiba, Tokyo (JP)

(21) Appl. No.: 13/306,875

(22) Filed: Nov. 29, 2011

(30) Foreign Application Priority Data
Nov. 30, 2010 (JP) P2010-267827

(51) Int. Cl. H03H 2/00

(52) U.S. Cl. 323/369; 323/364

(57) ABSTRACT

A power-supply-voltage detecting circuit in an embodiment includes a compensation circuit and a switching element which controls ON-and-OFF of the signal output of the signal circuit. The compensation circuit has a positive temperature coefficient to balance out the negative temperature coefficient that the switching element has.

### CROSS-REFERENCE TO RELATED APPLICATIONS

This application is based upon and claims the benefit of priority from the prior Japanese Patent Application No. 2010-267827, filed on Nov. 30, 2010; the entire contents of which are incorporated herein by reference.

### FIELD

Embodiments of the invention relate to a power-supply-voltage detecting circuit mounted in a semiconductor apparatus.

### BACKGROUND

A circuit to process and output signals at a predetermined power-supply voltage has a function to fix an output voltage until an internal circuit operates normally so as to prevent the output voltage from switching at an undesirable timing while the power-supply voltage is rising or falling in a transitional state.

A circuit of the related art controls a signal circuit by generating a comparative voltage from a band-gap reference voltage, and then making a comparator circuit compare the comparative voltage with a divided power-supply voltage.

If a small-scale circuit is demanded, a switching element to control the signal circuit is switched ON or OFF directly with the divided power-supply voltage. In this case, a detection voltage is an ON-voltage of the switching element multiplied by an inverse dividing ratio.

When the comparative voltage is generated from the band-gap reference voltage, the circuit tends to become larger in scale, which leads to an increase in cost in the case of a small-scale circuit such as a coupler.

In the case of a switching element directly controlled, a temperature dependency of the ON-voltage of the switching element makes the detection voltage also vary depending on the temperature. Hence, the power-supply-voltage varies depending on the temperature and is left unstable in such a wide voltage range that it is difficult to design circuits and apparatuses.

### BRIEF DESCRIPTION OF THE DRAWING

FIG. 1 is a circuit diagram illustrating a power-supply-voltage detecting circuit of a first embodiment.

FIG. 2 is a graph schematically illustrating the voltage characteristics of the power-supply-voltage detecting circuit of the first embodiment.

FIG. 3 is a graph illustrating the voltage-current characteristics for different temperatures of a switching element 3 of the first embodiment.

FIG. 4 is a circuit diagram illustrating a power-supply-voltage detecting circuit of a second embodiment.

FIG. 5 is a circuit diagram illustrating a power-supply-voltage detecting circuit of a third embodiment.

FIG. 6 is a circuit diagram according to a comparative example.

FIG. 7 is a graph illustrating the voltage-current characteristics for different temperatures of a switching element of the comparative example.

### DETAILED DESCRIPTION

A power-supply-voltage detecting circuit according to an embodiment includes a first resistor, a second resistor, a third resistor, a first semiconductor element, a second semiconductor element, and a third semiconductor element. A first end of the first resistor and a first end of the second resistor are connected to a common detection terminal. A first end of the third terminal is connected to the ground. The collector and the base of the first semiconductor element are connected in common to a second end of the first resistor. The emitter of the first semiconductor element is connected to the ground. The collector of the second semiconductor element is connected to a second end of the second resistor. The base of the second semiconductor element is connected to the collector and the base of the first semiconductor element and is also connected to the second end of the first resistor. The emitter of the second semiconductor element is connected to a second end of the third resistor. The collector of the third semiconductor element is connected to a signal circuit. The base of the third semiconductor element is connected in common to the collector of the second semiconductor element and to the second end of the second resistor. The emitter of the third semiconductor element is connected to the ground. The third semiconductor element switches the operational state of the signal circuit in accordance with the current flowing through the collector of the third semiconductor element.

### First Embodiment

Some embodiments of the invention will be described below by referring to the drawings.

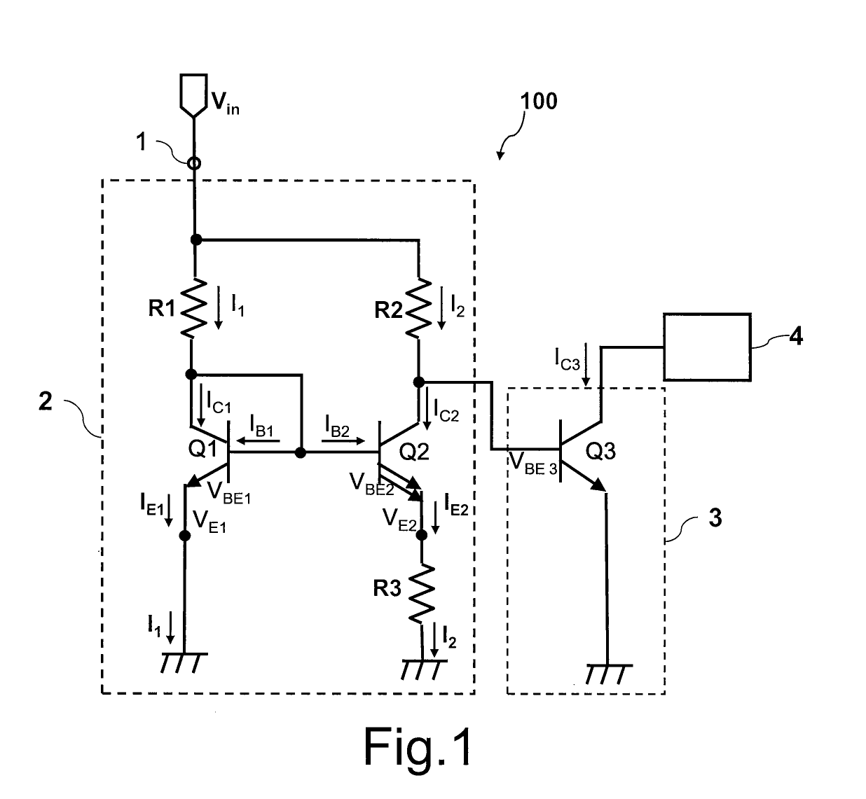

FIG. 1 is a circuit diagram illustrating a power-supply-voltage detecting circuit 100 of a first embodiment. The power-supply-voltage detecting circuit 100 includes a signal circuit 4, a switching element 3, and a compensation circuit 2. The signal circuit 4 is driven by the supply of power with either an input voltage Vin detected by a detection terminal 1 or a voltage proportional to the input voltage Vin. The switching element 3 controls the ON-and-OFF of the output from the signal circuit. The compensation circuit 2 generates a voltage drop with a positive temperature coefficient to balance out the negative temperature characteristics of the ON-voltage.

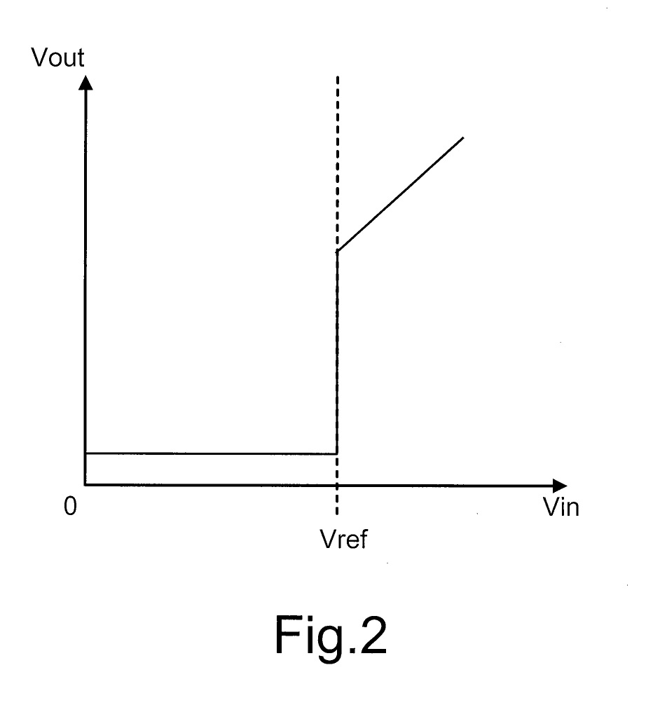

FIG. 2 is a graph schematically illustrating the voltage characteristics of the power-supply-voltage detecting circuit 100. As FIG. 2 shows, if the input voltage Vin such as a power-supply voltage given to the detection terminal 1 is equal to or higher than a threshold voltage Vref, for example, the switching element 3 is turned ON and the signal circuit 4 is enabled to output a signal with having an output voltage Vout at a High level. In contrast, if the output voltage of the compensation circuit 2 is equal to or lower than the threshold voltage Vref of the switching element 3, the signal circuit 4 outputs no signal with having the output voltage Vout at a Low or certain fixed level.

The compensation circuit 2 and the switching element 3 will be described in detail below. For the sake of descriptive convenience, the switching element 3 will be described first.

The switching element 3 is a semiconductor element. For example, as FIG. 1 shows, the switching element 3 may be a third NPN transistor. The third NPN transistor Q3 has a base electrode connected to the compensation circuit 2, and also has a collector electrode connected to the signal circuit 4. An emitter electrode of the transistor Q3 is connected to the ground. Like ordinary transistors, the third transistor Q3 has what is called a negative temperature coefficient of −2.6 mV/° C. approximately. Hence, the forward voltage between the base electrode and the emitter electrode of the third transistor Q3 becomes smaller with temperature rise. If a bias is imposed on the base electrode by resistive division, the threshold voltage Vref has a negative temperature coefficient. Accordingly, the power-supply-voltage detecting circuit 100 of this first embodiment is provided with the compensation circuit 2 capable of compensating the negative temperature coefficient of the third transistor Q3.

The compensation circuit 2 includes plural semiconductor elements and is designed to have a positive temperature coefficient while the third transistor Q3 (switching element 3) is ON for the purpose of balancing out the negative temperature coefficient of the third transistor Q3. For the sake of descriptive convenience, each of the semiconductor elements is assumed to be a diode or an NPN transistor. Specifically, the compensation circuit 2 includes: a first resistor R1 and a second resistor R2 both connected to the detection terminal 1; a first NPN transistor Q1 and a second NPN transistor Q2 of which base electrodes are connected to each other; and a third resistor R3 connected to an emitter electrode of the second transistor Q2.

The current amplification factor of the second transistor Q2 is set to be N times larger than each of the current amplification factors of the first transistor Q1 and of the third transistor Q3. To this end, an emitter-area ratio among the first to the third transistors Q1 to Q3 is set to be 1:N:1. In addition, a resistance ratio among the first to the third resistors R1 to R3 is set to be M:M:1.

Next, description will be given of why the power-supply-voltage detecting circuit 100 of this embodiment is less likely to be affected by the negative temperature coefficient while the switching element 3 is ON.

The input voltage Vin detected by the detection terminal 1 is expressed by the following Equation 1:

Vᵢₙ=R₂×I_{C2}+V_{BE3}

where

Vᵢₙ: Input voltage

R₂: Resistance of the second resistor R2

I_{c2}: Collector current of the second transistor Q2

V_{BE3}: Base-emitter voltage of the third transistor Q3.

In general, a base-emitter voltage VBE of a diode or a transistor has a negative temperature coefficient. Hence, the base-emitter voltage VBE is expressed by the following Equation 2 if the base-emitter voltage VBE at a temperature of 300 K (i.e., ordinary temperature of 27° C.) is expressed by VBE0, and the ordinary temperature coefficient of a transistor is expressed by −Y:

V_{BE}=V_{BE0}−Y×t

where

Y: Temperature coefficient (constant) of a transistor/diode

V_{BE}: Ordinary base-emitter voltage

V_{BE0}: Base-emitter voltage at ordinary temperature (27° C.).

In addition, the emitter voltage of the second transistor Q2 is expressed by the following Equation 3:

$$\begin{matrix}{V}_{\underline{E 2}} = {V}_{\underline{BE 1}} - {V}_{\underline{BE 2}} \\ = k \div q \times ( 300 + t ) \times ln ( N ) \\ = X \times ( 300 + t ) \times ln ( N )\end{matrix}$$

where

V_{E2}: Emitter voltage of second transistor Q

V_{BE1}: Base-emitter voltage of first transmitter Q1

V_{BE2}: Base-emitter voltage of second transmitter Q2

t: Varying temperature with a reference temperature of 27° C.

k: Boltzmann constant

q: Charge of electron

N: Emitter-area ratio

X: k/q.

With Equations 1 to 3, the input voltage Vin is expressed by the following Equation 4:

$$\begin{matrix}{V}_{\underline{in}} = {R}_{\underline{2}} \times {I}_{\underline{C 2}} + {V}_{\underline{BE 3}} \\ = {R}_{2} \times ( {V}_{\underline{E 2}} \div {R}_{\underline{3}} ) + {V}_{\underline{BE}} \\ = ( {R}_{\underline{2}} \div {R}_{\underline{3}} ) \times \{ X \times ( 300 + t ) \times ln ( N ) \} + {V}_{\underline{BE 0}} \times ( - Yt ) \\ = ( M \times X \times ln ( N ) - Y ) \times t + M \times X \times 300 \times ln ( N ) + {V}_{\underline{BE 0}}\end{matrix}$$

where

Vᵢₙ: Input voltage

V_{BE0}: Base-emitter voltage with a reference temperature of 27° C.

t: Temperature

N: Emitter-area ratio

M: Resistance ratio

X: Boltzmann constant k/Charge of electron q

Y: temperature coefficient (constant).

As described above, both the ratio X and the temperature coefficient Y are constants. Accordingly, the influence of the changing of the temperature while the third transistor Q3 (switching element 3) is ON can be precluded simply by setting the values of M and N in Equation 4 to satisfy the following Equation 5:

(M×X×1n(N)−Y)=0

where

N: Emitter-area ratio

M: Resistance ratio

Y: temperature coefficient (constant) of a transistor/diode.

As has been described thus far, in the power-supply-voltage detecting circuit 100 of this first embodiment, simply by determining the resistance ratio M and the emitter-area ratio N to satisfy the above-mentioned Equation 5, the stable input voltage Vin from which the influence of the temperature change is precluded is easily detected by the detection terminal 1 while the switching element 3 is ON.

### Comparative Example

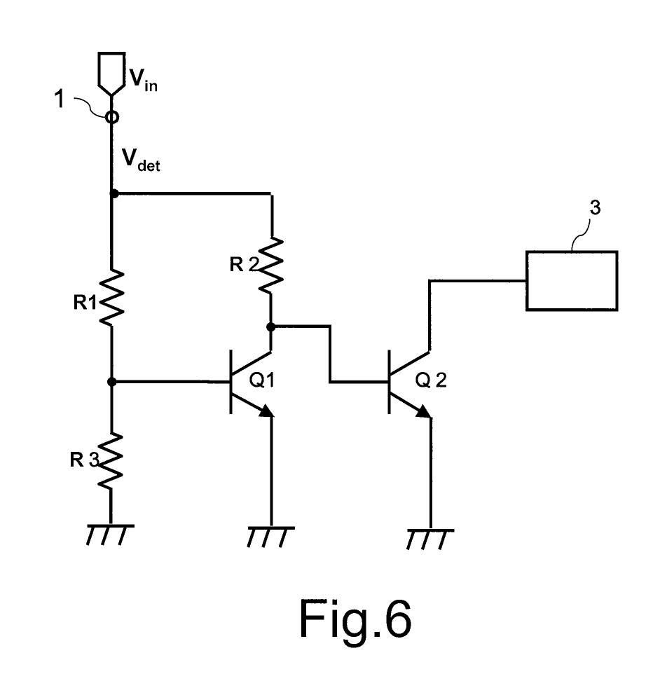

FIG. 6 is a circuit diagram according to a comparative example. The comparative example includes a first resistor R1, a second resistor R2, a third resistor R3, a first transistor Q1, a second NPN transistor Q2, and a signal circuit 4. An input voltage Vin is inputted into a first end of the first resistor R1 and a first end of the second resistor R2. The first end of the first resistor R1 and the first end of the second resistor R2 are connected to each other. A second end of the second resistor R2 is connected to a collector electrode of the first transistor Q1. The third resistor R3 is connected to a base electrode of the first transistor Q1. The second NPN transistor Q2 is connected to the collector electrode of the first transistor Q1. The signal circuit 4 is connected to a collector electrode of the second NPN transistor Q2 serving as a switching element. As FIG. 6 shows, unlike in the power-supply-voltage detecting circuit 100, the first transistor Q1 of the comparative example does not form a current-mirror circuit.

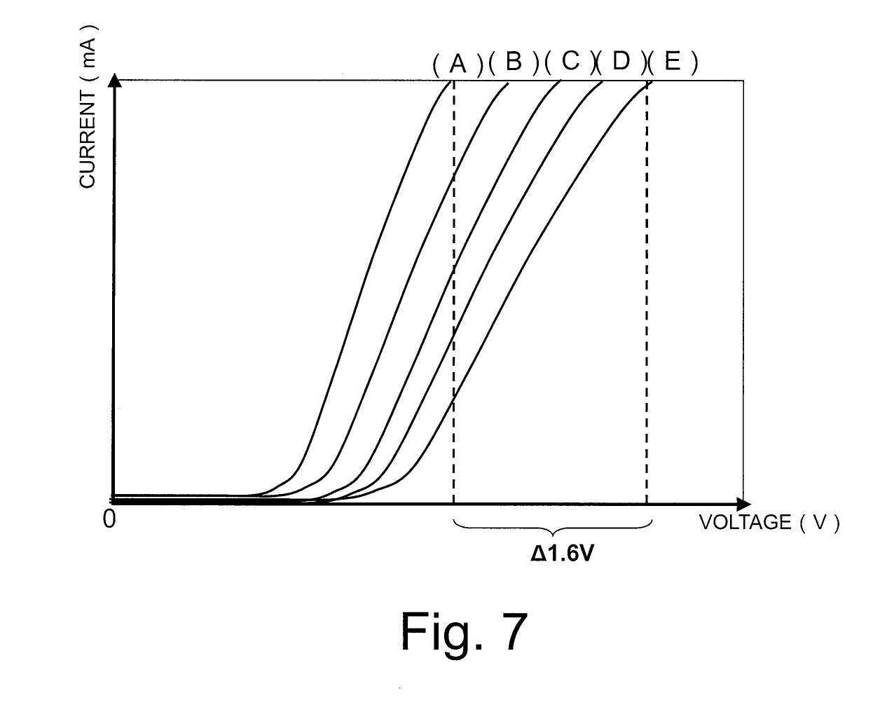

FIG. 7 is a graph illustrating the voltage-current characteristics for different temperatures of the switching element, i.e., the second transistor Q2, of the comparative example. The vertical axis of the graph represents the collector current of the second transistor Q2 whereas the horizontal axis represents the input voltage Vin. For example, the curved line (A) represents the voltage-current characteristics at 150° C., the curved line (B) represents those at 100° C., the curved line (C) represents those at 50° C., the curved line (D) represents those at 0° C., and the curved line (E) represents those at −50° C. As FIG. 7 shows, the voltage-current characteristics in the comparative example vary depending on the temperature of the switching element, that is, the second transistor Q2.

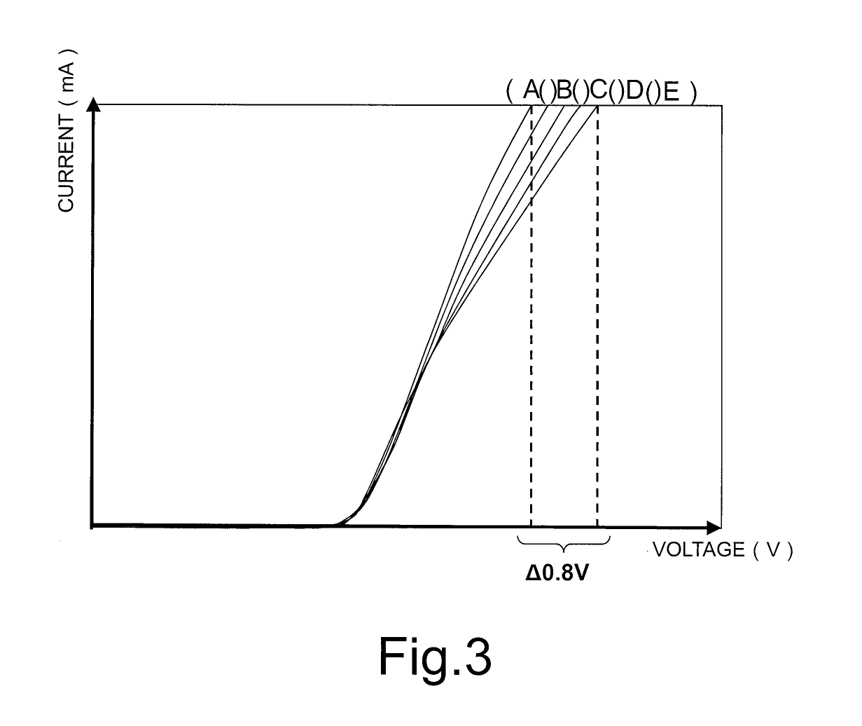

FIG. 3 is a graph illustrating exemplar voltage-current characteristics for different temperatures of the switching element 3, i.e., the third transistor Q3, of this embodiment. The vertical axis of the graph represents the collector current of the third transistor Q3 whereas the horizontal axis represents the base-emitter voltage of the third transistor Q3. Also, form the left in the figure, the curved line (A) represents the voltage-current characteristics at 150° C., the curved line (B) represents those at 100° C., the curved line (C) represents those at 50° C., the curved line (D) represents those at 0° C., and the curved line (E) represents those at −50° C. As FIG. 3 shows, according to this embodiment, the difference between the curved line (A) representing the case of the highest temperature of the switching element, i.e., the third transistor Q3, and the curved line (E) representing the case of the lowest temperature of the switching element can be reduced.

As has been described thus far, the power-supply-voltage detecting circuit 100 of this embodiment can balance out the negative temperature coefficient of the switching element 3 and thereby preclude the influence of the changing of the temperature simply by setting the value of the resistance ratio M and that of the emitter-area ratio N to satisfy the above-mentioned Equation 5. Consequently, the unstable-voltage range of the power-supply-voltage detecting circuit 100 can be reduced, and stable operation of the apparatus as a whole can be made possible.

Note that in this first embodiment, the resistance ratio among the resistors are set to be M:M:1, and the emitter-area ratio among the transistors are set to be 1:N:1. Those ratios, however, are not the only possible ones.

### Second Embodiment

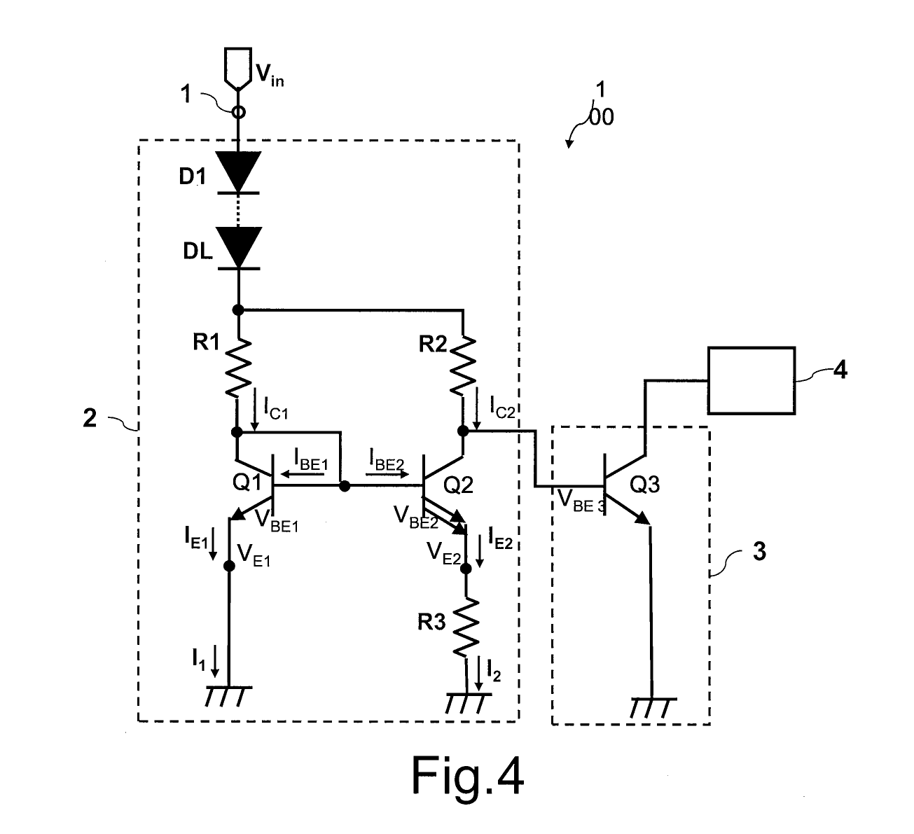

FIG. 4 is a circuit diagram illustrating a power-supply-voltage detecting circuit 100 of a second embodiment. As FIG. 4 shows, in this embodiment, diodes D are connected, in series, to a 0-to-L stage-detection circuit 1. In this embodiment, by adjusting the number of diode stages in each of which an input voltage Vin is inputted into the anode electrode, the input voltage Vin to turn a switching element can be set appropriately.

This is represented by the following Equation 6:

$$\begin{matrix}{V}_{\underline{in}} = {R}_{\underline{2}} \times {I}_{\underline{C 2}} + {V}_{\underline{BE 3}} + L \times {V}_{\underline{BED}} \\ = {R}_{\underline{2}} ( {V}_{\underline{E 2}} \div {R}_{\underline{3}} ) + ( 1 + L ) \times {V}_{\underline{BE}} \\ = \{ X \times M \times ln ( N ) - ( 1 + L ) \times Y \} \times t + X \times M \times 300 \times \\ ln ( N ) + ( 1 + L ) \times {V}_{\underline{BE 0}}\end{matrix}$$

where

Vᵢₙ: Input voltage

V_{BE0}: Base-emitter voltage with a reference temperature of 27° C.

X: Boltzmann constant k/Charge of electron q

Y: temperature coefficient (constant)

M: Resistance ratio

N: Emitter-area ratio

L: Number of diode stages

t: Temperature.

As has been described thus far, in this embodiment, if the number of diodes L is adjusted appropriately, and if the value of the resistance ratio M and the value of the emitter-area ratio N in the temperature-coefficient portion in the above-mentioned Equation 6 are set to satisfy an equation, X×M×1n(N)−(1+L)=0, it is possible to preclude the temperature-dependent variation of the input voltage Vin at the timing when the switching element 2 is turned ON.

### Third Embodiment

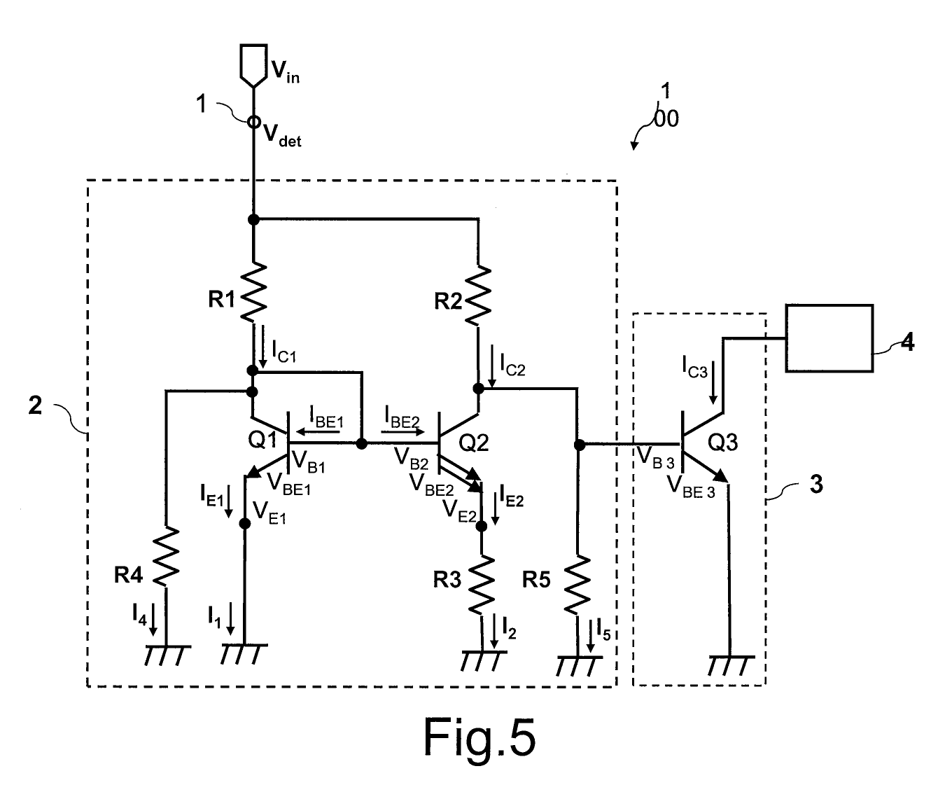

FIG. 5 is a circuit diagram illustrating a power-supply-voltage detecting circuit 100 of a third embodiment. As FIG. 5 shows, this embodiment additionally includes a fourth resistor R4 and a fifth resistor R5. The fourth resistor R4 is provided between a collector electrode of a first transistor Q1 and the ground. The fifth resistor R5 is provided between a base electrode of a third transistor Q3 and the ground.

In this embodiment, by adjusting the values of the resistors R4 and R5 appropriately, the input voltage Vin of the timing when the switching element 3 is turned ON can be set appropriately.

This is expressed by Equation 7 to be given below.

If the resistance ratio R1:R2:R3:R4:R5 are set to be M:M:1:K:K, the current I4 is equal to the current I5, that is, the current I1 is equal to the current I2 under the conditions where the third transistor Q3 is turned ON.

Accordingly the current Ic2 flowing through the second resistor R2 is expressed by the following equation.

Ic2=I2+I5=(VE2÷R3}+(VBE3÷R5)

Hence the voltage Vin detected by the detector terminal is expressed by the following Equation 7:

$$\begin{matrix}{V}_{\underline{in}} = {R}_{\underline{2}} \times {I}_{\underline{C 2}} + {V}_{\underline{BE 3}} \\ = {R}_{\underline{2}} \div {R}_{\underline{3}} \times {V}_{\underline{E 2}} + ( {R}_{\underline{2}} \div {R}_{\underline{5}} + 1 ) \times {V}_{\underline{BE 3}} \\ = \{ M \times X \times ln ( N ) - ( M \div K + 1 ) \times Y \} \times t + X \times M \times 300 \times \\ ln ( N ) + ( M \div K + 1 ) \times {V}_{BE 0} \}\end{matrix}$$

where

Vᵢₙ: Input voltage

X: Boltzmann constant k/Charge of electron q (constant)

Y: temperature coefficient (constant)

M: Resistance ratio

K: Resistance ratio

L: Number of diode stages

t: Temperature.

As has been described thus far, in this embodiment, if the arbitrarily-determined values of M, N, and K in the temperature-coefficient portion in the above-mentioned Equation 7 are adjusted appropriately to satisfy a equation M×X×1n(N)−(M÷K+1)×Y=0, it is possible to preclude the temperature-dependent variation of the input voltage Vin at the timing when the third transistor Q3 is turned ON.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A power-supply-voltage detecting circuit comprising:
a first resistor and a second resistor both having first ends connected in common to a detection terminal;
a third resistor having a first end connected to the ground;
a first semiconductor element having a first electrode connected to a second end of the first resistor, a second electrode connected to the first electrode, and a third electrode connected to the ground;
a second semiconductor element having a first electrode connected to a second end of the second resistor, a second electrode connected in common to the second electrode of the semiconductor element and the second end of the first resistor, and a third electrode connected to a second end of the third resistor; and
a third semiconductor element having a first electrode connected to a signal circuit, a second electrode connected in common to the first electrode of the second semiconductor element and the second end of the second resistor, and a third electrode connected to the ground, the third semiconductor element switching an operational state of the signal circuit in accordance with a current flowing through the first electrode.

2. The power-supply-voltage detecting circuit according to claim 1, wherein any of the first and the second resistors has a potential difference with such positive temperature characteristics as to balance out negative temperature characteristics that the third semiconductor element has between the second and third electrodes.

3. The power-supply-voltage detecting circuit according to claim 1, wherein if a resistance ratio among the first resistor, the second resistor, and the third resistor is M:M:1, and if an emitter-area ratio among the first semiconductor element, the second semiconductor element, and the third semiconductor element is 1:N:1, the values of M and N satisfy the following equation:
(M×X×1n(N)−Y)=0
where
X: Quotient obtained by dividing Boltzmann constant by electrical charge, and
Y: Temperature coefficient of the semiconductor element.

4. The power-supply-voltage detecting circuit according to claim 2, wherein if a resistance ratio among the first resistor, the second resistor, and the third resistor is M:M:1, and if an emitter-area ratio among the first semiconductor element, the second semiconductor element, and the third semiconductor element is 1:N:1, the values of M and N satisfy the following equation:
(M×X×1n(N)−Y)=0
where
X: Quotient obtained by dividing Boltzmann constant by electrical charge, and
Y: Temperature coefficient of the semiconductor element.

5. The power-supply-voltage detecting circuit according to claim 1 further comprising at least one diode connected, in series, between the detection terminal and a connection point between the first resistor and the second resistor.

6. The power-supply-voltage detecting circuit according to claim 2 further comprising at least one diode connected, in series, between the detection terminal and a connection point between the first resistor and the second resistor.

7. The power-supply-voltage detecting circuit according to claim 3 further comprising at least one diode connected, in series, between the detection terminal and a connection point between the first resistor and the second resistor.

8. The power-supply-voltage detecting circuit according to claim 4 further comprising at least one diode connected, in series, between the detection terminal and a connection point between the first resistor and the second resistor.

9. The power-supply-voltage detecting circuit according to claim 1 further comprising:
a fourth resistor connected between the third electrode of the first semiconductor element and the ground; and
a fifth resistor connected between the third electrode of the second semiconductor element and the ground.

10. The power-supply-voltage detecting circuit according to claim 2 further comprising:
a fourth resistor connected between the third electrode of the first semiconductor element and the ground; and
a fifth resistor connected between the third electrode of the second semiconductor element and the ground.

11. The power-supply-voltage detecting circuit according to claim 3 further comprising:
a fourth resistor connected between the third electrode of the first semiconductor element and the ground; and
a fifth resistor connected between the third electrode of the second semiconductor element and the ground.

12. The power-supply-voltage detecting circuit according to claim 4 further comprising:
a fourth resistor connected between the third electrode of the first semiconductor element and the ground; and
a fifth resistor connected between the third electrode of the second semiconductor element and the ground.

13. The power-supply-voltage detecting circuit according to claim 5 further comprising:
a fourth resistor connected between the third electrode of the first semiconductor element and the ground; and
a fifth resistor connected between the third electrode of the second semiconductor element and the ground.

14. The power-supply-voltage detecting circuit according to claim 6 further comprising:
a fourth resistor connected between the third electrode of the first semiconductor element and the ground; and
a fifth resistor connected between the third electrode of the second semiconductor element and the ground.

15. The power-supply-voltage detecting circuit according to claim 7 further comprising:
a fourth resistor connected between the third electrode of the first semiconductor element and the ground; and
a fifth resistor connected between the third electrode of the second semiconductor element and the ground.

16. The power-supply-voltage detecting circuit according to claim 8 further comprising:
a fourth resistor connected between the third electrode of the first semiconductor element and the ground; and
a fifth resistor connected between the third electrode of the second semiconductor element and the ground.

17. The power-supply-voltage detecting circuit according to claim 9 further comprising:
a fourth resistor connected between the third electrode of the first semiconductor element and the ground; and
a fifth resistor connected between the third electrode of the second semiconductor element and the ground.
